(19) United States
(12) Patent Application Publication
(10) Pub. No.: US 2006/0226735 A1
(43) Pub. Date: Oct. 12, 2006

(54) Semiconductor device formed by using MEMS technique

(75) Inventor: Tamio Ikehashi, Yokohama-shi (JP)

Correspondence Address: FOLEY AND LARDNER LLP;SUITE 500, 3000 K STREET NW, WASHINGTON, DC, 20007, US

(73) Assignee: KABUSHIKI KAISHA TOSHIBA

(21) Appl. No.: 11/280,385

(22) Filed: Nov. 17, 2005

(30) Foreign Application Priority Data
Apr. 11, 2005 (JP) 2005-113483

(51) Int. Cl. H01L 41/00

(52) U.S. Cl. 310/311

(57) ABSTRACT

A semiconductor device includes an elastic member, first and second electrodes, a piezoelectric actuator, and an electrostatic actuator. One end of the elastic member is fixed on a substrate through an anchor so as to form a gap between the elastic member and the substrate. The first and second electrodes are placed to face the other end of the elastic member and the substrate, respectively. The piezoelectric actuator deforms the other end of the elastic member to bring it close to the substrate. The electrostatic actuator includes a third electrode placed in the elastic member and a fourth electrode placed on the substrate so as to face the third electrode, and deforms the other end of the elastic member so as to bring it close to the substrate. The distance between the first and second electrodes is changed by driving the piezoelectric actuator and the electrostatic actuator.

### CROSS-REFERENCE TO RELATED APPLICATIONS

This application is based upon and claims the benefit of priority from prior Japanese Patent Application No. 2005-113483, filed Apr. 11, 2005, the entire contents of which are incorporated herein by reference.

### BACKGROUND OF THE INVENTION

1. Field of the Invention

The present invention relates to a semiconductor device such as a variable capacitor or switch formed by using a micromachining, or MEMS, (Micro-Electro-Mechanical Systems) technique.

2. Description of the Related Art

A variable capacitor or switch manufactured by using the MEMS technique is advantageous over that using a PIN diode or FET in that, for example, the loss is small (the Q value is large) and distortion is small. Such devices are therefore expected to be mounted in next-generation cellular phones.

As driving schemes for these MEMS variable capacitors and switches, an electrostatic type scheme, piezoelectric type scheme, thermal type scheme, electromagnetic type scheme, and the like are used. Of these schemes, the thermal type scheme and electromagnetic type scheme consume high power and hence are not suitable to be mounted in portable devices. In contrast, the electrostatic type scheme (see, for example, U.S. Pat. No. 5,578,976) consumes low power but has the following drawbacks:

i) The driving voltage is high.

ii) Sticking occurs due to charge trapping by an insulating film.

In a MEMS variable capacitor with an inter-electrode distance of about 1 μm, in order to make the electrodes contact with each other by using electrostatic attraction, a high voltage of about 20V is required. Since this voltage is higher than the power supply voltage of a cellular phone system, a component or circuit which generates a high voltage is required, resulting in an increase in cost. In addition, as a high voltage is generated, the power consumption increases. It is known that in an electrostatic type variable capacitor or switch, charge is trapped in the insulating film between electrodes owing to this high voltage. The amount of charge trapped by one switching operation is small. However, as switching is repeated, a large amount of charge is stored, and the pull-out voltage shifts. If this shift amount becomes large, the electrodes are kept in contact with each other and do not separate from each other (sticking). It is known that such sticking occurs when switching is repeated 10⁶ times or more.

In contrast, a piezoelectric type variable capacitor or switch can be driven by a low voltage of 5V or lower, and the power consumption is low (see, for example, H. C. Lee et al., “Silicon Bulk Micromachined RF MEMS Switches with 3.5 Volts Operation by using Piezoelectric Actuator”, MTT-S Digest, pp. 585-588, 2004). However, since the driving force is weak, the contact force is about 10 μN, which is 1/10 that of an electrostatic type device. The following problems therefore arise:

iii) In a MEMS switch, the contact resistance is high.

iv) In a MEMS variable capacitor, the adhesion between electrodes is poor (Even if the electrodes have minute recesses or warpage, strong driving force can bring the electrodes into tight contact with each other. If the driving force is weak, the electrodes cannot be brought into tight contact with each other, resulting in a reduction in variable width.)

As described above, electrostatic type and piezoelectric type variable capacitors and switches are suitable to be mounted in portable devices as compared with thermal type and electromagnetic type devices, but have both merits and demerits in terms of characteristics and functions associated with driving voltage, sticking, contact resistance, the adhesion between electrodes, and the like. None of them are sufficient, are required to be improved.

### BRIEF SUMMARY OF THE INVENTION

According to an aspect of the present invention, there is provided a semiconductor device comprising an elastic member having one end which is fixed on a substrate through an anchor so as to form a gap between the one end and the substrate and is deformed to change a distance between the substrate and the other end of the elastic member, a first electrode which is placed at the other end of the elastic member, a second electrode which is placed on the substrate so as to face the first electrode, a piezoelectric actuator which is placed in the elastic member and is deformed to bring the other end of the elastic member close to the substrate, and an electrostatic actuator which includes a third electrode placed in the elastic member and a fourth electrode placed on the substrate so as to face the third electrode and is deformed to bring the other end of the elastic member close to the substrate, wherein a distance between the first electrode and the second electrode is changed by driving the piezoelectric actuator and the electrostatic actuator.

According to another aspect of the present invention, there is provided a semiconductor device comprising an elastic member having two ends which are fixed on a substrate through a first anchor and second anchor so as to form a gap in a middle portion and is deformed to change a distance between the middle portion and the substrate, a first electrode which is placed at the middle portion of the elastic member, a second electrode which is placed on the substrate so as to face the first electrode, a first piezoelectric actuator and a second piezoelectric actuator which are placed in the elastic member with the first electrode being placed therebetween and deform the middle portion of the elastic member so as to bring the middle portion close to the substrate, and an electrostatic actuator which includes a third electrode and fourth electrode placed in the elastic member with the first electrode being placed therebetween, and a fifth electrode and sixth electrode placed on the substrate to face the third electrode and the fourth electrode, and deforms the middle portion of the elastic member to bring the middle portion close to the substrate, wherein a distance between the first electrode and the second electrode is changed by driving the first piezoelectric actuator and second piezoelectric actuator and the first electrostatic actuator and second electrostatic actuator.

### BRIEF DESCRIPTION OF THE SEVERAL VIEWS OF THE DRAWING

FIG. 1 is a plan view of a variable capacitor to explain a semiconductor device according to the first embodiment of the present invention;

FIG. 2 is a sectional view taken along a line II-II′ in FIG. 1 to explain the semiconductor device according to the first embodiment of the present invention;

FIG. 3 is a sectional view taken along a line III-III′ in FIG. 1 to explain the semiconductor device according to the first embodiment of the present invention;

FIG. 4 is a block diagram of a cellular phone equipped with a terrestrial digital broadcast receiving function to explain an application example of the semiconductor device according to the first embodiment of the present invention;

FIG. 5 is a circuit diagram showing an example of the specific arrangement of a driver in the circuit shown in FIG. 4;

FIG. 6 is a circuit diagram showing another example of the specific arrangement of the driver in the circuit shown in FIG. 4;

FIG. 7 is a circuit diagram showing an example of the specific arrangement of a matching circuit in the circuit shown in FIGS. 4 to 6;

FIG. 8 is a plan view showing the pattern layout of the matching circuit shown in FIG. 7;

FIG. 9 is a plan view of a variable capacitor to explain a semiconductor device according to the second embodiment of the present invention;

FIG. 10 is a sectional view taken along a line X-X′ in FIG. 9 to explain the semiconductor device according to the second embodiment of the present invention;

FIG. 11 is a plan view of a variable capacitor to explain a semiconductor device according to the third embodiment of the present invention;

FIG. 12 is a plan view of a variable capacitor to explain a semiconductor device according to the fourth embodiment of the present invention;

FIG. 13 is a plan view of a variable capacitor to explain a semiconductor device according to the fifth embodiment of the present invention;

FIG. 14 is a sectional view taken along a line XIV-XIV′ in FIG. 13 to explain the semiconductor device according to the fifth embodiment of the present invention;

FIG. 15 is a plan view of a variable capacitor to explain a semiconductor device according to the sixth embodiment of the present invention;

FIG. 16 is a sectional view taken along a line XVI-XVI′ in FIG. 15 to explain the semiconductor device according to the sixth embodiment of the present invention;

FIG. 17 is a plan view of a switch to explain a semiconductor device according to the seventh embodiment of the present invention;

FIG. 18 is a sectional view taken along a line XVIII-XVIII′ in FIG. 17 to explain the semiconductor device according to the seventh embodiment of the present invention;

FIG. 19 is a schematic view for explaining the first driving method for the semiconductor device according to the second embodiment of the present invention;

FIG. 20 is a timing chart showing the relationship between the voltage applied to each terminal and the capacitive value when the first driving method is used;

FIG. 21 is a schematic view for explaining the second driving method for the semiconductor device according to the second embodiment of the present invention;

FIG. 22 is a timing chart showing the relationship between the voltage applied to each terminal and the capacitive value when the second driving method is used;

FIG. 23 is a schematic view for explaining the third driving method for the semiconductor device according to the second embodiment of the present invention;

FIG. 24 is a timing chart showing the relationship between the voltage applied to each terminal and the capacitive value when the third driving method is used;

FIG. 25 is a schematic view for explaining the fourth driving method for the semiconductor device according to the second embodiment of the present invention;

FIG. 26 is a timing chart showing the relationship between the voltage applied to each terminal and the capacitive value when the fourth driving method is used;

FIG. 27 is a schematic view for explaining the fifth driving method for the semiconductor device according to the second embodiment of the present invention;

FIG. 28 is a timing chart showing the relationship between the voltage applied to each terminal and the capacitive value when the fifth driving method is used;

FIG. 29 is a circuit diagram showing a VCO circuit equipped with a MEMS variable capacitor to explain another example of the semiconductor device according to the embodiments of the present invention; and

FIG. 30 is a circuit diagram showing an example of an arrangement in a case wherein a MEMS switch for a multiband cellular pone is used to explain still another application example of the semiconductor device according to the embodiments of the present invention.

### DETAILED DESCRIPTION OF THE INVENTION

### First Embodiment

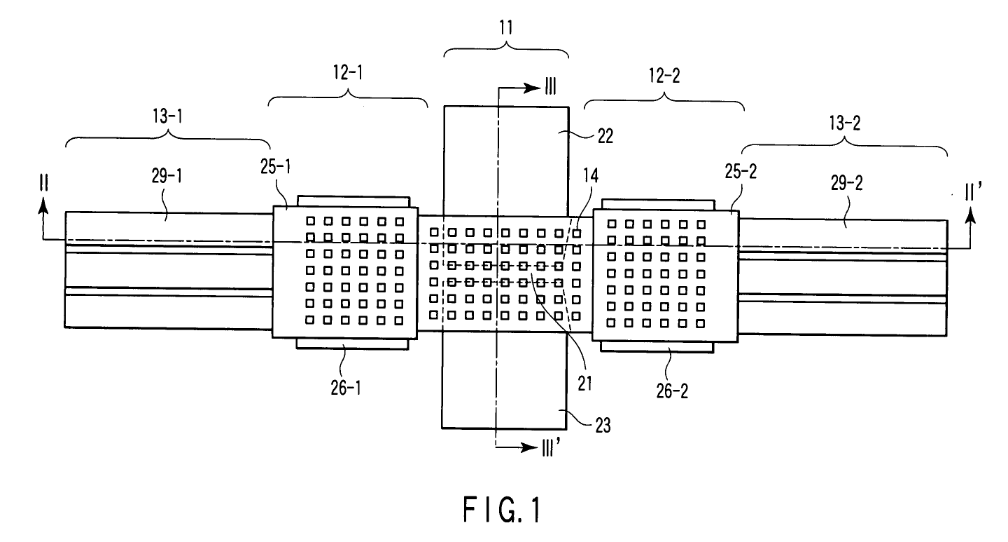

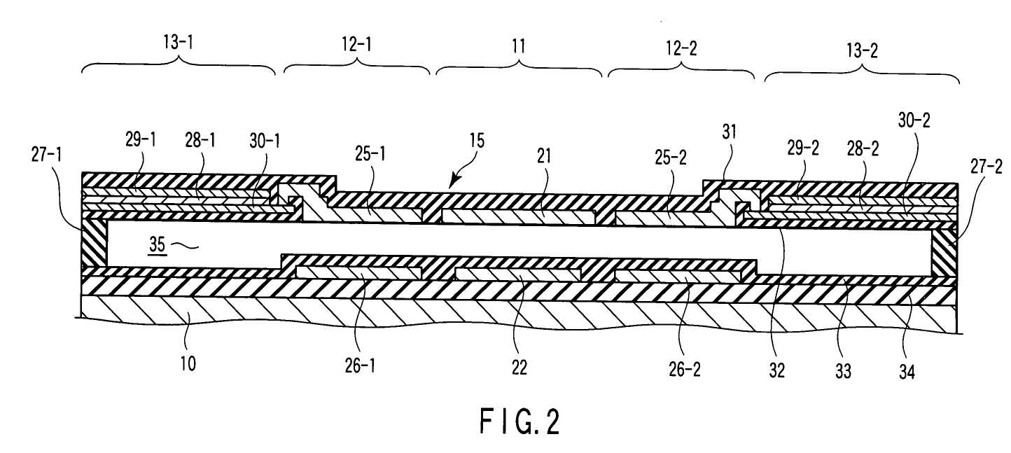

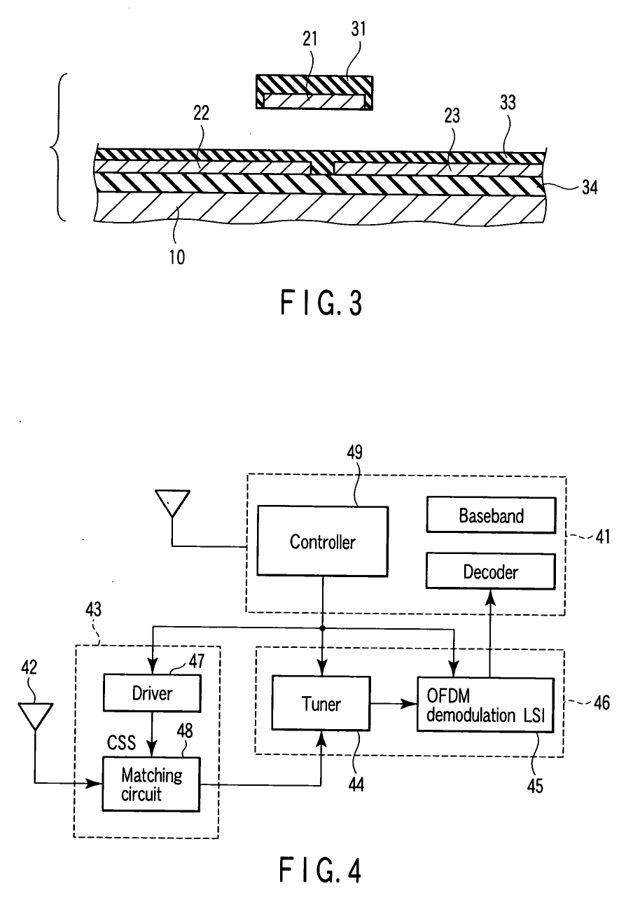

FIGS. 1 to 3 are views for explaining a semiconductor device according to the first embodiment of the present invention. FIG. 1 is a plan view of a variable capacitor. FIG. 2 is a sectional view taken along a line II-II′ in FIG. 1. FIG. 3 is a sectional view taken along a line III-III′ in FIG. 1. This semiconductor device comprises a variable capacitor unit 11, electrostatic actuator units 12-1 and 12-2, and piezoelectric actuator units 13-1 and 13-2. The piezoelectric actuator unit 13-1, electrostatic actuator unit 12-1, variable capacitor unit 11, electrostatic actuator unit 12-2, and piezoelectric actuator unit 13-2 are linearly arranged in one direction. These units are formed in a structure formed such that the two ends of an elastic member 15 are fixed on a substrate (e.g., a silicon substrate) 10 with anchors 27-1 and 27-2. A hollow 35 is formed between the elastic member 15 and the substrate 10. When the piezoelectric actuator units 13-1 and 13-2 and the electrostatic actuator units 12-1 and 12-2 are driven, the middle portion (variable capacitor unit 11) of the elastic member 15 deforms to move closer to the substrate 10, and the distance between the elastic member 15 and the substrate 10 changes.

The variable capacitor unit 11 comprises an upper electrode 21 formed in the elastic member 15 and lower electrodes 22 and 23 formed on the substrate 10. The upper electrode 21 is a floating electrode. When this electrode is driven by the actuator units 12-1, 12-2, 13-1, and 13-2, the inter-electrode distance changes. When the upper electrode 21 of the variable capacitor unit 11 is lowered by the actuator units 12-1, 12-2, 13-1, and 13-2, the upper electrode 21 moves close to the lower electrodes 22 and 23. As a result, the lower electrodes 22 and 23 are capacitively coupled to each other. While the upper electrode 21 is located at the upper position, a gap of about 1.5 μm is formed between the upper electrode 21 and an insulating film 33. In this state, the capacitance between the lower electrodes 22 and 23 is negligibly small. As described above, moving the upper electrode 21 up and down makes it possible to form a digital variable capacitor whose capacitive value changes in a binary manner.

A hybrid-type actuator which controls the inter-electrode distance of the variable capacitor unit 11 will be described next. The above electrostatic actuator units 12-1 and 12-2 are arranged on the two sides of the variable capacitor unit 11, and are comprised of upper electrodes 25-1 and 25-2 and lower electrodes 26-1 and 26-2, respectively. The piezoelectric actuator units 13-1 and 13-2 are respectively provided between the electrostatic actuator units 12-1 and 12-2 and the anchors 27-1 and 27-2 on the two sides. The piezoelectric actuator units 13-1 and 13-2 include piezoelectric films 28-1 and 28-2 and upper electrodes 29-1 and 29-2 and lower electrodes 30-1 and 30-2 which are respectively arranged to sandwich piezoelectric films 28-1 and 28-2. As a material for the piezoelectric films 28-1 and 28-2, AlN, PZT, or the like is used.

The insulating film 31 is formed on the upper electrode 21 of the variable capacitor unit 11, the upper electrodes 25-1 and 25-2 of the electrostatic actuator units 12-1 and 12-2, and the upper electrodes 29-1 and 29-2 of the piezoelectric actuator units 13-1 and 13-2. An insulating film 32 is formed under the lower electrodes 30-1 and 30-2 of the piezoelectric actuator units 13-1 and 13-2. The lower electrodes 22 and 23 of the variable capacitor unit 11 and the lower electrodes 26-1 and 26-2 of the electrostatic actuator units 12-1 and 12-2 are formed on an insulating film 34 formed on the substrate 10. The insulating film 33 is formed on the lower electrodes 22, 23, 26-1, and 26-2.

In the above arrangement, when a potential difference is applied between the upper electrodes 29-1 and 29-2 and lower electrodes 30-1 and 30-2 of the piezoelectric actuator units 13-1 and 13-2, the piezoelectric films 28-1 and 28-2 are displaced, and the other end of the elastic member 15 is displaced downward. As the piezoelectric actuator units 13-1 and 13-2, either unimorph type actuators or bimorph type actuators can be used. When the upper electrodes 21, 25-1, and 25-2 are displaced downward by applying the first potential difference between the upper electrodes 29-1 and 29-2 and lower electrodes 30-1 and 30-2 of the piezoelectric actuator units 13-1 and 13-2, the upper electrodes 25-1 and 25-2 move close to the lower electrodes 26-1 and 26-2. In this state, the second potential difference is applied between the upper electrodes 25-1 and 25-2 and the lower electrodes 26-1 and 26-2. The second potential difference may be equal to the first potential difference or may be smaller or larger than the first potential difference. This displaces the upper electrode 21 of the variable capacitor unit 11 downward, and the distance between the upper electrode 21 and the lower electrodes 22 and 23 decreases. As a consequence, the capacitive value changes in a binary manner.

The upper electrode 21 of the variable capacitor unit 11 can be displaced upward and restored to the initial state by eliminating the potential difference between the piezoelectric actuator units 13-1 and 13-2 after or at the same time as eliminating the potential difference between the electrostatic actuator units 12-1 and 12-2.

In the above arrangement, since the displacement amounts of the piezoelectric actuator units 13-1 and 13-2 are large, this device can be operated even if the first potential difference is 5V or less. In general, in order to drive the electrostatic actuator units 12-1 and 12-2, a high potential difference of 20V or more is required. In this embodiment, the electrostatic actuator units 12-1 and 12-2 are driven while the inter-plate distance (inter-electrode distance) is shortened by driving the piezoelectric actuator units 13-1 and 13-2. Since the electrostatic attraction between the plates is proportional to the square of the reciprocal of the inter-plate distance, even if, therefore, the potential difference between the electrodes is equal to or lower than the first potential difference, sufficiently strong electrostatic attraction can be obtained. This makes it possible to ensure high adhesion between the upper electrode 21 and lower electrodes 22 and 23 of the variable capacitor unit 11.

In the arrangement of this embodiment, since the potential difference between the plates of the electrostatic actuator units 12-1 and 12-2 is small, charge trapping does not easily occur in the insulating film 33. This allows to increase the number of times of switching as compared with the prior art.

In addition, windows 14 formed in the variable capacitor unit 11 and electrostatic actuator units 12-1 and 12-2 in FIG. 1 in the form of matrices serve to make the progress of etching uniform in the etching step of forming the hollow 35. These windows also contribute to a reduction in air resistance, and hence allow high-speed switching. Obviously, the windows 14 are not indispensable, and the substantial effects of the present invention do not change without the windows.

In this embodiment, the lower electrodes 30-1 and 30-2 of the electrostatic actuator units 12-1 and 12-2 are short-circuited (connected) to the upper electrodes 25-1 and 25-2 of the electrostatic actuator units 12-1 and 12-2. However, substantially the same functions and effects as those of the above arrangement can be obtained even if the upper electrodes 29-1 and 29-2 for piezoelectric driving are short-circuited to the upper electrodes 25-1 and 25-2 of the electrostatic actuator units 12-1 and 12-2. In addition, the upper electrodes 25-1 and 25-2 and lower electrodes 30-1 and 30-2 of the electrostatic actuator units 12-1 and 12-2 may be independently controlled.

The variable capacitor of this embodiment described above is suitable to be used for the antenna matching circuit of a cellular phone, e.g., a cellular phone capable of receiving terrestrial digital broadcasts. Such an application example will be described below.

FIG. 4 is a block diagram showing a cellular phone equipped with a terrestrial digital broadcast receiving function. A back-end system 41 in FIG. 4 is a system provided for a conventional cellular phone. The newly added component for terrestrial digital broadcast reception is a front system 46 comprising an antenna 42 for terrestrial digital broadcast reception, a matching circuit system 43, a tuner 44, and an OFDM demodulation LSI 45. The matching circuit system 43 described above functions to prevent a reduction in bandwidth due to antenna mismatch loss, and includes a driver 47 and matching circuit 48.

The matching circuit system 43 will be described in more detail next.

Terrestrial digital broadcasts are aired by using electric waves in the UHF band of 470 to 770 MHz (wavelengths of 63 cm to 39 cm). Since the wavelength of electric waves is long, when this terrestrial digital broadcast is to be received by a dipole antenna, the antenna needs to have a length of about 15 cm. As to recent cellular phones, great importance is especially attached to design, and hence it is required to minimize the length of an antenna. If possible, an antenna is preferably built into the housing of a cellular phone. If, however, the antenna is simply reduced in size, the bandwidth decreases, resulting in incapability of receiving signals with all frequencies of 470 to 770 MHz. In order to avoid this problem, the matching circuit 48 is provided to change the matching frequency in accordance with a desired program. The matching circuit 48 may be formed from, for example, a variable capacitor, and the matching frequency may be changed by changing the capacitive value of the variable capacitor.

Another problem in reducing the antenna size is that the antenna efficiency deteriorates. The antenna efficiency is determined by the radiation resistance of the antenna itself and the loss resistance that occurs between the antenna and the reception circuit and is expressed by
antenna efficiency=radiation resistance/(radiation resistance+loss resistance)

As the antenna is reduced in size, the radiation resistance decreases. Therefore, the antenna efficiency deteriorates unless the loss radiation decreases. If, for example, a PIN diode is used as the variable capacitor of the matching circuit 48, the antenna efficiency deteriorates because the loss resistance is large. In contrast, a MEMS device has a small loss resistance, which can be suppressed to 1Ω or less. If, therefore, a MEMS variable capacitor is used for the matching circuit 48, a compact antenna can be realized and can be built into the housing of a cellular phone.

On the basis of the above consideration, the matching circuit 48 in the matching circuit system 43 in FIG. 4 comprises the semiconductor device (variable capacitor) shown in FIGS. 1 to 3. Channel select information output from a controller 49 of the back-end system 41 is input to the driver 47, tuner 44, and OFDM demodulation LSI 45. The channel select information input to the driver 47 is input to the matching circuit 48 upon being converted into a capacitive value selection signal CSS.

FIG. 5 is a circuit diagram showing an example of the specific arrangement of the driver 47 in the circuit shown in FIG. 4. Channel select information is in the form of a binary signal, and is input to the driver 47 through, for example, an I² C bus. This binary signal is decoded by a decoder 51 in the driver 47. When a decoded signal Si (i=1, . . . , n) output from the decoder 51 is activated (for example, is set at “High” of “High” and “Low”), a switch SWi is turned on to output ith fuse data fuse-i as the capacitive value selection signal CSS. This signal is input to the matching circuit 48. In this manner, the capacitive value of the matching circuit 48 changes in accordance with channel select information, and the antenna can be matched with the frequency band of the selected broadcasting station.

The fuse data fuse-i (i=1, . . . , n) is used as the capacitive value selection signal CSS to compensate for variations in the capacitive value of the MEMS variable capacitor and the effect of the parasitic capacitance of the matching circuit 48. The fuse data fuse-i is determined in the following manner in a test step. First of all, the capacitive value selection signal CSS is output to a test circuit 52 and is changed step by step until the capacitive value of the matching circuit 48 changes its minimum value to its maximum value. In this case, the capacitive value of the matching circuit 48 is monitored by a tester. The fuse data fuse-i in the driver 47 is then determined so as to realize a capacitive value corresponding to channel select information in accordance with this monitored value. The determination of this fuse data fuse-i is performed by, for example, laser blow.

Note that a nonvolatile memory may be used in place of a fuse.

In addition, if variations in the capacitive value of the MEMS variable capacitor and the effect of the parasitic capacitance of the matching circuit 48 are sufficiently small and need not be compensated for, the test circuit may be omitted, and the fuses may be replaced with ROMs (ROM-1, . . . , ROM-n).

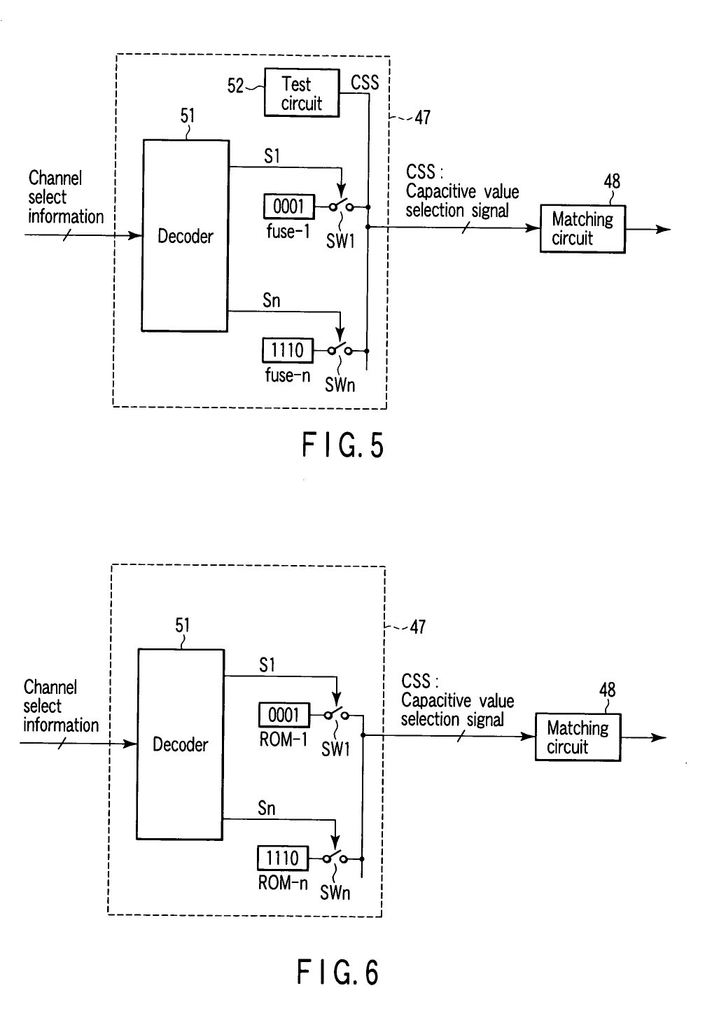

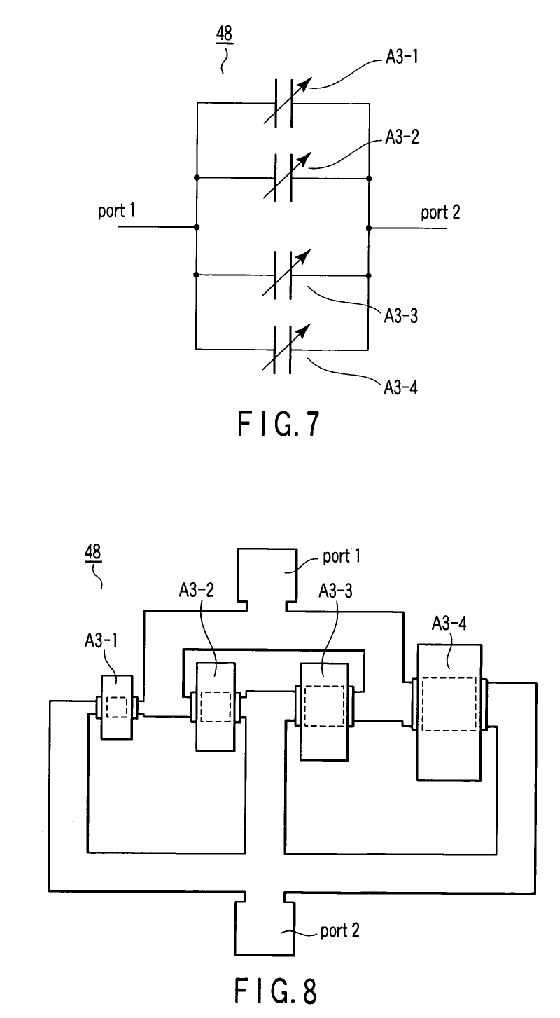

FIG. 7 shows an example of the specific arrangement of the matching circuit 48 in the circuit shown in FIGS. 4 to 6. Referring to FIG. 7, capacitors A3-1, . . . , A3-4 are MEMS variable capacitors whose capacitive values can be changed in a digital manner (binary manner) by actuators. One electrode port1 of these capacitors A3-1, . . . , A4-4 is connected to an antenna, and the other electrode port2 is connected to a ground point.

For example, FIG. 8 shows the pattern layout of the matching circuit 48. Each of capacitors A3-j (j=1, 2, 3, 4) is a digital variable capacitor which can realize a capacitive value of 2^{j-1}C or 0. Allocating capacitive values in a binary manner in this manner allows the four digital variable capacitors to change the capacitive value to four different values of 1C, 2C, 4C, and 8C each, i.e., a total of 16 different capacitive values. Obviously, this is an example, and the number of digital variable capacitors to be used may be other than four.

Using the arrangement shown in FIGS. 1 to 3 as that of the digital variable capacitors (capacitors A3-1, . . . , A3-4) shown in FIGS. 7 and 8 makes it possible to realize the low-voltage, low-power-consumption matching circuit 48. Since the hybrid device is formed by using both the piezoelectric type device and the electrostatic type device, which makes the most of the merits of the two types and compensates for their demerits, even if the area of the capacitor unit is increased, excellent adhesion can be ensured. Therefore, the above binary variable arrangement can be used, and the total chip area of the matching circuit 48 can be reduced.

### Second Embodiment

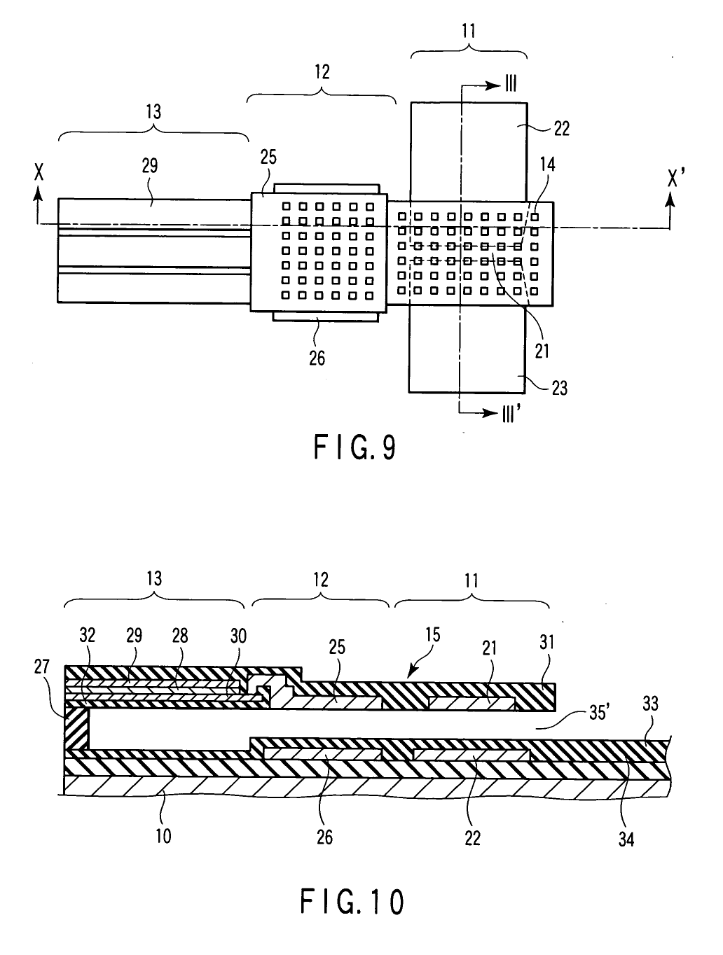

FIGS. 9 and 10 are views for explaining a semiconductor device according to the second embodiment of the present invention. FIG. 9 is a plan view of a variable capacitor. FIG. 10 is a sectional view taken along a line X-X′ in FIG. 9. A cross-section taken along a line III-III′ in FIG. 9 is the same as that in FIG. 3.

This semiconductor device comprises a variable capacitor unit 11, electrostatic actuator unit 12, and piezoelectric actuator unit 13. These units are formed in a structure formed such that one end of an elastic member 15 is fixed on a substrate (e.g., a silicon substrate) 10 with an anchor 27. A hollow 35′ is formed between the elastic member 15 and the substrate 10. When the piezoelectric actuator unit 13 and the electrostatic actuator unit 12 are driven, the other end (an upper electrode 21 of the variable capacitor unit 11) of the elastic member 15 deforms to move close to the substrate 10 (a lower electrode 22 of the variable capacitor unit 11), and the distance between the elastic member 15 and the substrate 10 changes.

The same reference numerals as in FIGS. 1 and 2 denote the same parts in FIGS. 9 and 10, and a detailed description thereof will be omitted.

That is, according to the second embodiment, the elastic member 15 is cantilevered. With such an arrangement as well, the device operates basically in the same manner as in the first embodiment, and substantially the same functions and effects as those in the first embodiment can be obtained.

### Third Embodiment

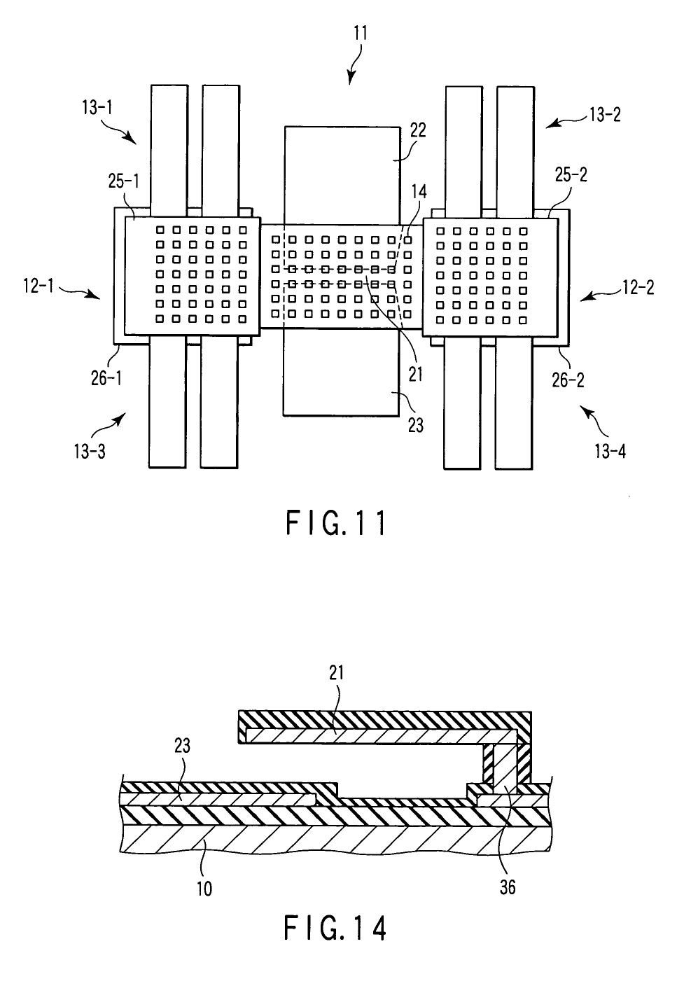

FIG. 11 is a view for explaining a semiconductor device according to the third embodiment of the present invention. FIG. 11 is a plan view of a variable capacitor. This semiconductor device comprises a variable capacitor unit 11, electrostatic actuator units 12-1 and 12-2, and piezoelectric actuator units 13-1, 13-2, 13-3, and 13-4. In the third embodiment, the variable capacitor unit, electrostatic actuator units, and piezoelectric actuator units are not arranged linearly, but the piezoelectric actuator units 13-1, 13-2, 13-3, and 13-4 are arranged nonlinearly. More specifically, the piezoelectric actuator units 13-1 and 13-3 are arranged on the opposite sides of the electrostatic actuator unit 12-1, and the piezoelectric actuator units 13-2 and 13-4 are arranged on the opposite side of the electrostatic actuator unit 12-2.

With such an arrangement as well, the device operates basically in the same manner as in the first embodiment, and substantially the same functions and effects as those in the first embodiment can be obtained. In addition, the tensile stress of an elastic member 15 can be reduced and the capacitive value can be effectively changed with small force as compared with the case wherein the variable capacitor unit, electrostatic actuator units, and piezoelectric actuator units are arranged linearly.

Note that the elastic member 15 in the third embodiment may be cantilevered, as in the second embodiment.

### Fourth Embodiment

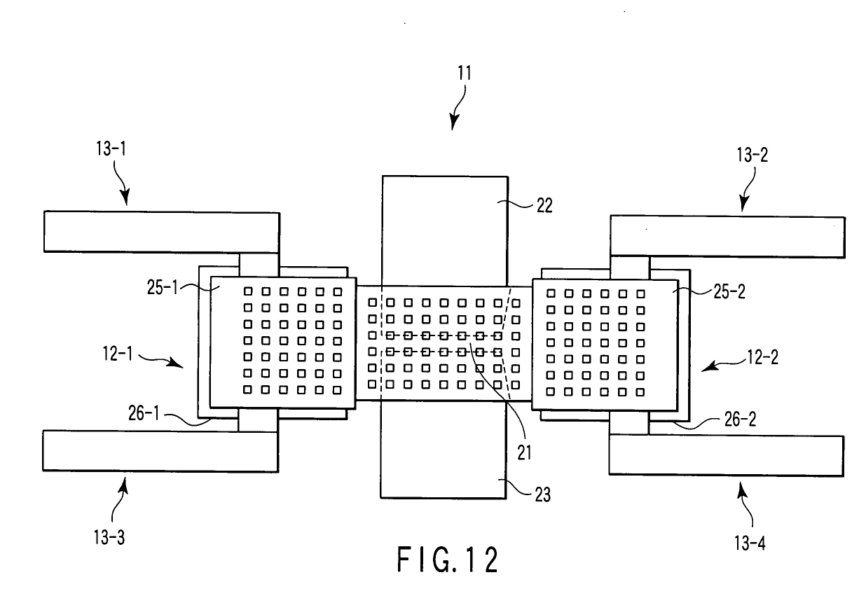

FIG. 12 is a view for explaining a semiconductor device according to the fourth embodiment of the present invention. FIG. 12 is a plan view of a variable capacitor. This semiconductor device comprises a variable capacitor unit 11, electrostatic actuator units 12-1 and 12-2, and piezoelectric actuator units 13-1, 13-2, 13-3, and 13-4. In the fourth embodiment, the piezoelectric actuator units 13-1, 13-2, 13-3, and 13-4 are formed in a flexure pattern on a plane.

With such an arrangement as well, the device operates basically in the same manner as in the first and third embodiments, and substantially the same functions and effects as those in the first and third embodiments can be obtained. In addition, since the flexure portions of the piezoelectric actuator units 13-1, 13-2, 13-3, and 13-4 serve as springs, the capacitive value can be effectively changed with small force.

Obviously, the elastic member 15 can be cantilevered as in the second embodiment.

### Fifth Embodiment

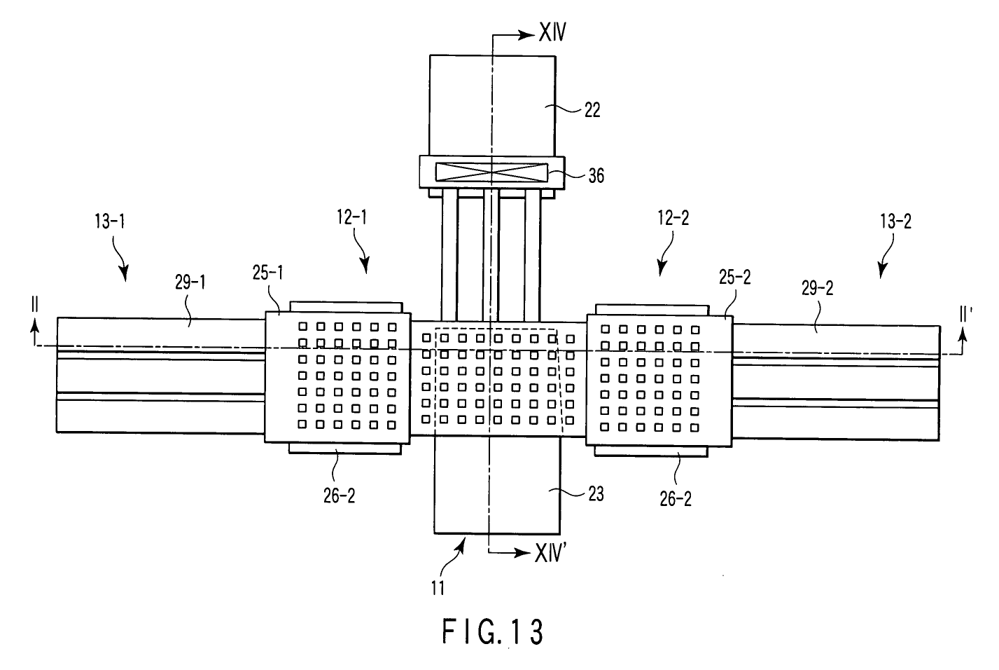

FIGS. 13 and 14 are views for explaining a semiconductor device according to the fifth embodiment of the present invention. FIG. 13 is a plan view of a variable capacitor. FIG. 14 is a sectional view taken along a line XIV-XIV′ in FIG. 13. A cross-section taken along a line II-II′ in FIG. 13 is the same as that in FIG. 2.

In this semiconductor device, an upper electrode 21 of a variable capacitor unit 11 is not floating but is fixed with a contact 36. This makes it possible to apply a potential to the upper electrode 21 through the contact 36.

With such an arrangement as well, the device operates basically in the same manner as in the first embodiment, and substantially the same functions and effects as those in the first embodiment can be obtained. In addition, since the upper electrode 21 can be electrically fixed, the capacitance of the variable capacitor unit 11 can increase. Since it suffices to provide one lower electrode for the variable capacitor unit 11, the pattern occupying area can be reduced. Furthermore, grounding the upper electrode 21 in advance can prevent charge-up in a manufacturing process.

Obviously, the elastic member 15 can be cantilevered as in the second embodiment.

### Sixth Embodiment

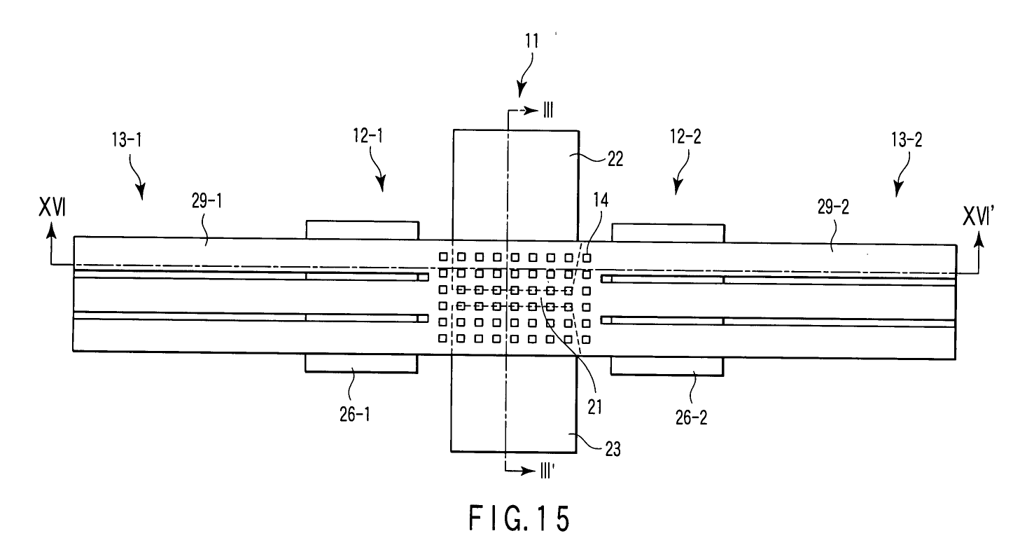

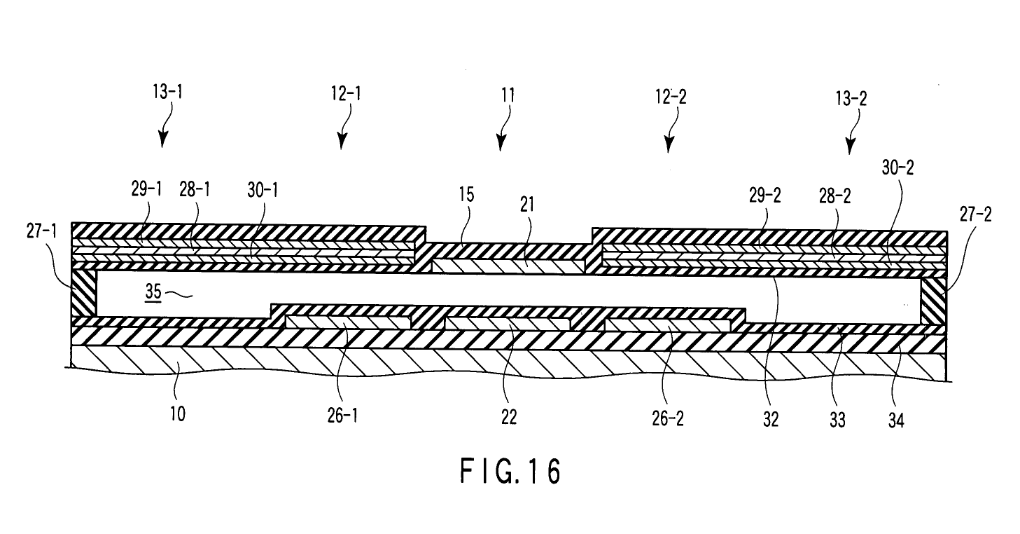

FIGS. 15 and 16 are views for explaining a semiconductor device according to the sixth embodiment of the present invention. FIG. 15 is a plan view of a variable capacitor. FIG. 16 is a sectional view taken along a line XVI-XVI′ in FIG. 15. A cross-section taken along a line III-III′ in FIG. 15 is the same as that in FIG. 3.

In the sixth embodiment, piezoelectric films 28-1 and 28-2, upper electrodes 29-1 and 29-2, and lower electrodes 30-1 and 30-2 of piezoelectric actuator units 13-1 and 13-2 are made to extend so as to face lower electrodes 26-1 and 26-2 of electrostatic actuator units 12-1 and 12-2. In other words, the lower electrodes 30-1 and 30-2 are used as the upper electrodes of the electrostatic actuator units 12-1 and 12-2.

With such an arrangement as well, the device operates basically in the same manner as in the first embodiment, and substantially the same functions and effects as those in the first embodiment can be obtained.

Obviously, the elastic member 15 can be cantilevered as in the second embodiment.

### Seventh Embodiment

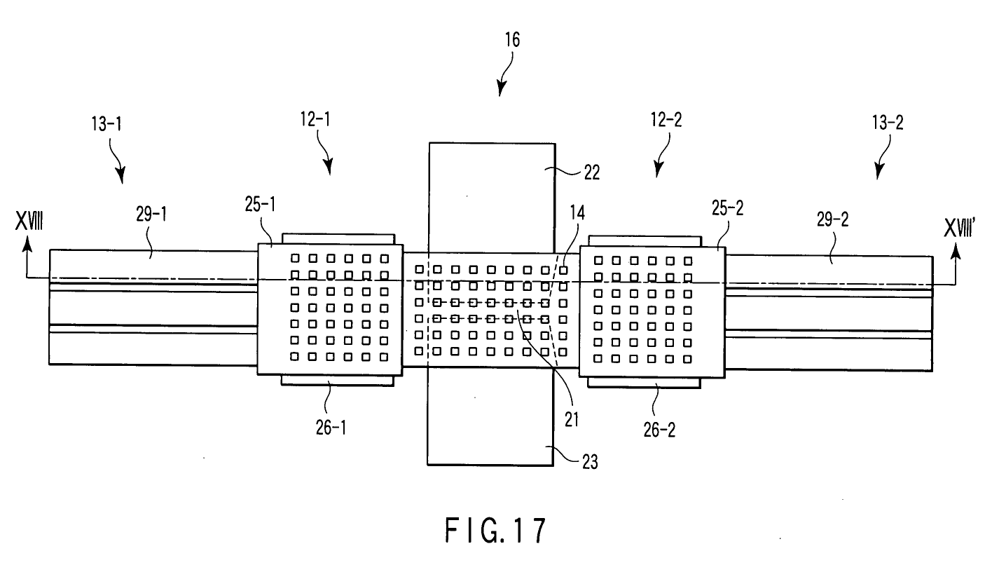

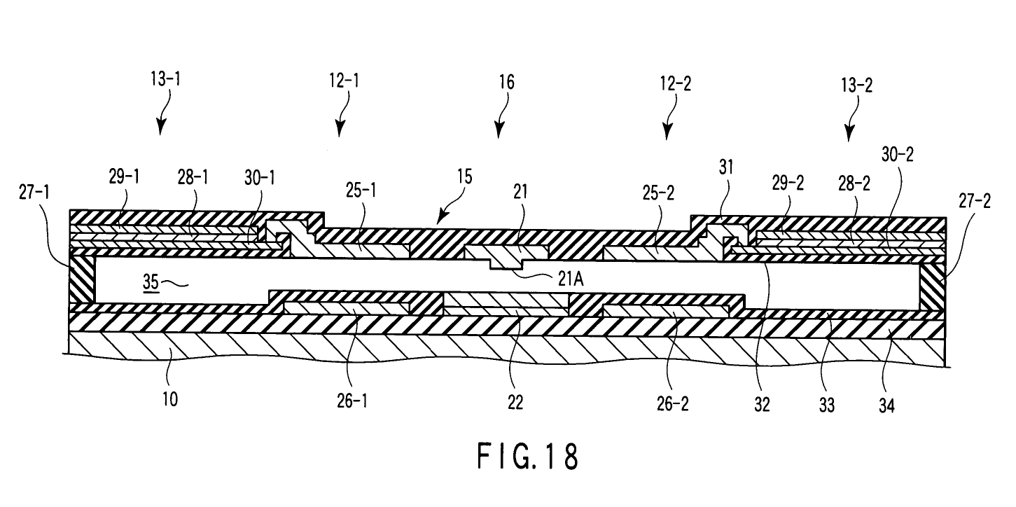

FIGS. 17 and 18 are views for explaining a semiconductor device according to the seventh embodiment of the present invention. FIG. 17 is a plan view of a switch. FIG. 18 is a sectional view taken along a line XVIII-XVIII′ in FIG. 17.

This semiconductor device comprises a switch unit 16, electrostatic actuator units 12-1 and 12-2, and piezoelectric actuator units 13-1 and 13-2. These units are formed in a structure such that the two ends of an elastic member 15 are fixed on a substrate (e.g., a silicon substrate) 10 with anchors 27-1 and 27-2. A hollow 35 is formed between the elastic member 15 and the substrate 10. When the piezoelectric actuator units 13-1 and 13-2 and the electrostatic actuator units 12-1 and 12-2 are driven, the middle portion (switch unit 16) of the elastic member 15 deforms to move close to the substrate 10, thereby turning on/off the switch.

The same reference numerals as in FIGS. 1 and 2 denote the same parts in FIGS. 17 and 18, and a detailed description thereof will be omitted.

That is, the variable capacitor unit 11 in FIGS. 1 and 2 is replaced with the switch unit 16. The switch unit 16 comprises an upper electrode 21 and lower electrodes 22 and 23. Since the upper electrode 21 and lower electrodes 22 and 23 are exposed, preferably, gold or platinum is used for these electrodes to prevent an increase in contact resistance or a contact failure when they are exposed to air and oxidized. The upper electrode 21 is a floating electrode, which can be moved up and down by the electrostatic actuator units 12-1 and 12-2 and piezoelectric actuator units 13-1 and 13-2. When the upper electrode 21 of the switch unit 16 is lowered by the actuator units 12-1, 12-2, 13-1, and 13-2, a projection 21A of the upper electrode 21 comes into contact with the lower electrodes 22 and 23 to be electrically connected (switched on).

While the upper electrode 21 is located at the upper position, a gap of about 1.5 μm is formed between the upper electrode 21 and an insulating film 33 (switched off). By moving the upper electrode 21 up and down in this manner, the switch can be turned on/off.

Note that the elastic member 15 may be cantilevered as in the second embodiment. In addition, the electrostatic actuator units 12-1 and 12-2, the piezoelectric actuator units 13-1 and 13-2, and piezoelectric actuator units 13-3 and 13-4 may be arranged as in the third embodiment or may be arranged as in the fourth embodiment. Furthermore, obviously, as in the fifth embodiment, the upper electrode 21 can be fixed with a contact 36.

Various driving methods will be described by taking the variable capacitor as the semiconductor device according to the second embodiment as an example.

(First Driving Method)

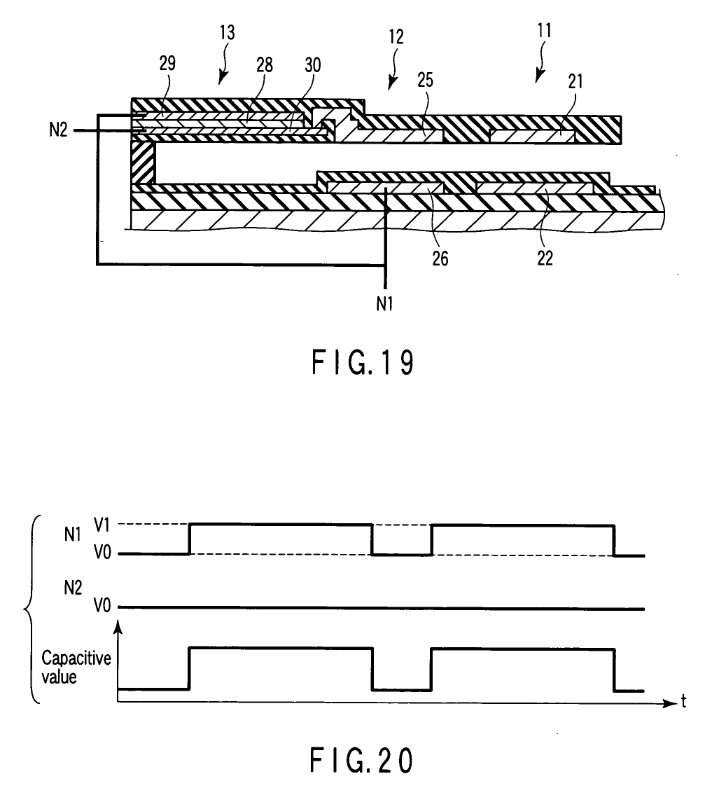

FIG. 19 is a schematic view for explaining the first driving method for the semiconductor device according to the second embodiment of the present invention. FIG. 20 shows the relationship between the voltage applied to each terminal and the capacitive value in this driving method. When the upper electrode 29 of the piezoelectric actuator unit 13 is short-circuited (a terminal N1) to the lower electrode 26 of the electrostatic actuator unit 12 and a voltage V0 is applied to the lower electrode 30 (a terminal N2) of the piezoelectric actuator unit 13, the capacitive value is stabilized in a predetermined state. When the upper electrode 21 of the variable capacitor unit 11 is to be lowered, the voltage at the terminal N1 is raised from V0 to V1 while the terminal N2 is kept at the voltage V0. For example, the voltage V0 is set to 0V, and the voltage V1 is set to 3V.

With this operation, the upper electrode 21 of the variable capacitor unit 11 moves close to the lower electrodes 22 and 23 to increase the capacitive value.

The voltage waveforms at the terminals N1 and N2 in the timing chart of FIG. 20 may be interchanged. In this case, the polarization direction of the piezoelectric film 28 and the thicknesses of the upper electrode 29 and lower electrode 30 for piezoelectric driving are adjusted to warp the piezoelectric actuator unit 13 downward upon application of a voltage.

(Second Driving Method)

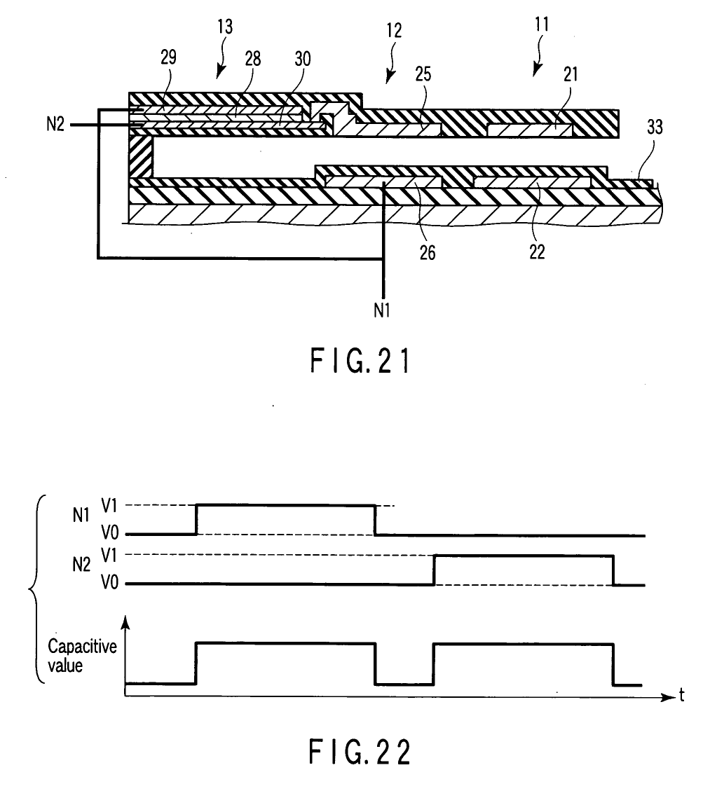

FIG. 21 is a schematic view for explaining the second driving method for the semiconductor device according to the second embodiment of the present invention. FIG. 22 shows the relationship between the voltage applied to each terminal and the capacitive value in this driving method. In this example of driving operation, a terminal to which a voltage V1 is applied is alternately changed like N1→N2→N1→N2→ . . . . With this operation, the direction of an electric field applied to the insulating film 33 of the electrostatic actuator unit 12 changes for every switching operation. This makes it less easy for charge to be trapped in the insulating film 33. As a result, the number of times of switching can be increased over 10⁶.

In this case, PZT is used for the piezoelectric film 28. The thickness and composition of a PZT film are determined so as to invert the polarization at the voltage V1 or lower. This makes it possible to always displace the piezoelectric actuator unit 13 downward even if the direction of an electric field changes.

(Third Driving Method)

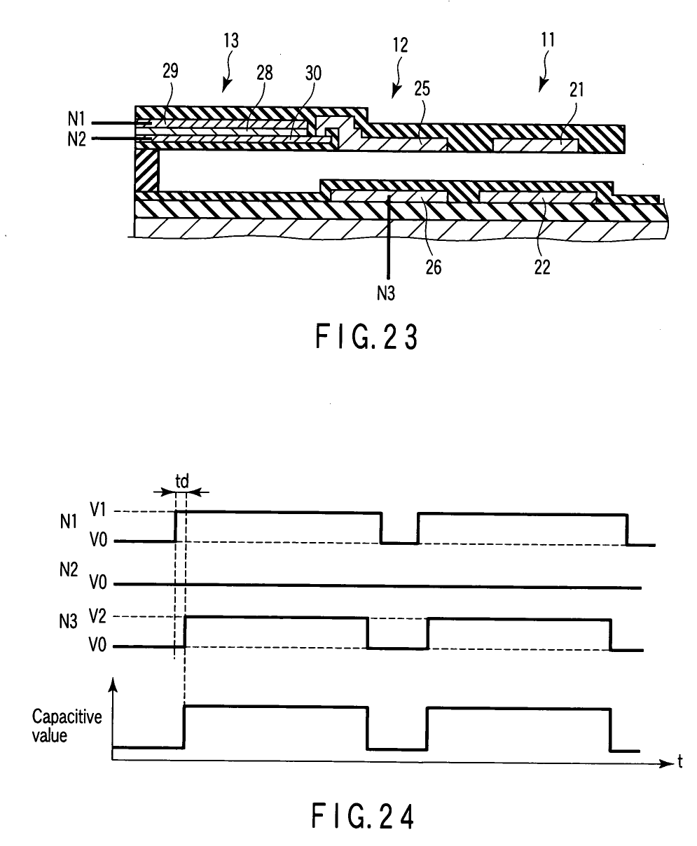

FIG. 23 is a schematic view for explaining the third driving method for the semiconductor device according to the second embodiment of the present invention. FIG. 24 shows the relationship between the voltage applied to each terminal and the capacitive value in this driving method. The upper electrode 29 of the piezoelectric actuator unit 13 and the lower electrode 26 of the electrostatic actuator unit 12 are used as different terminals N1 and N3, and the timings of the application of voltages are shifted from each other by td, as shown in FIG. 24.

This can reduce the peak current value at switching and suppress a drop in power supply voltage. The above delay time td is set to, for example, 100 ns. Referring to FIG. 24, the potential at the terminal N1 rises earlier than that at the terminal N3 by td. However, the potential at the terminal N3 may be made to rise earlier than that at the terminal N1. In addition, voltages V1 and V2 applied to the terminals N1 and N3 may be the same or different.

(Fourth Driving Method)

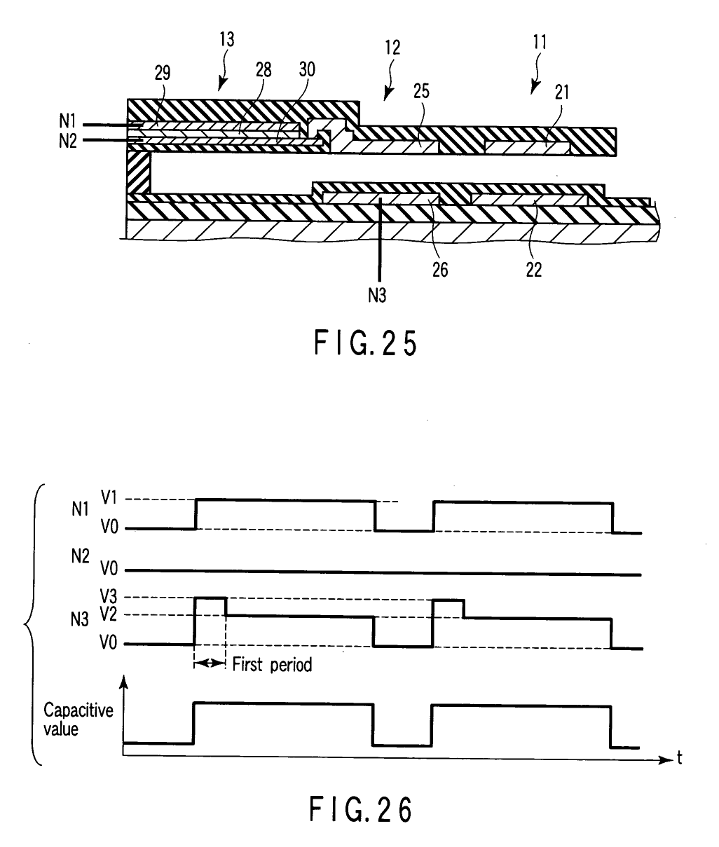

FIG. 25 is a schematic view for explaining the fourth driving method for the semiconductor device according to the second embodiment of the present invention. FIG. 26 shows the relationship between the voltage applied to each terminal and the capacitive value in this driving method. In this example of driving operation, a voltage V3 higher than a voltage V2 is applied to a terminal N3 only for the first period of each leading edge. This makes it possible to increase the electrostatic attraction between the electrodes only for the first period and improve the adhesion between the electrodes. Once the electrodes come into tight contact with each other, the inter-electrode distance becomes short and the electrostatic attraction becomes strong. This state can therefore be maintained at a lower voltage (V2). More specifically, for example, the voltage V2 may be set to 3V, the voltage V3 may be set to 5V, and the first period is set to 1 μs.

(Fifth Driving Method)

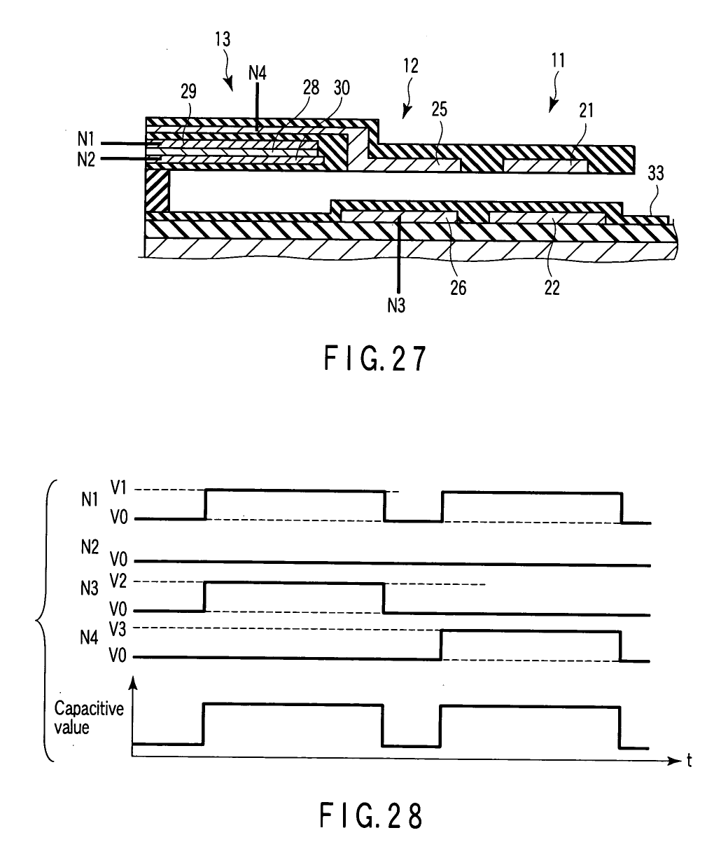

FIG. 27 is a schematic view for explaining the fifth driving method for the semiconductor device according to the second embodiment of the present invention. FIG. 28 shows the relationship between the voltage applied to each terminal and the capacitive value in this driving method. In this example of driving operation, the driving electrode of the piezoelectric actuator unit 13 is completely separated from the driving electrode of the electrostatic actuator unit 12. Driving voltages like those shown in FIG. 28 are applied to terminals N1, N2, N3, and N4.

With this operation, the same effect as that in the second driving method can be expected with respect to the insulating film 33 of the electrostatic actuator unit 12. In addition, since the upper electrode 25 of the electrostatic actuator unit 12 is separated from the electrodes 29 and 30 of the piezoelectric actuator unit 13, AlN, which has no polarization inversion characteristic, can be used for the piezoelectric film 28.

The use of AlN reduces fatigue due to polarization inversion as compared with the case wherein PZT is used, and hence allows to increase the number of times of switching.

Note that a driving method based on a combination of some of the first to fifth driving methods may be used. Although the driving methods for the second embodiment have been exemplified, it is obvious that the present invention can be applied to the variable capacitors and switches of all the embodiments in the same manner.

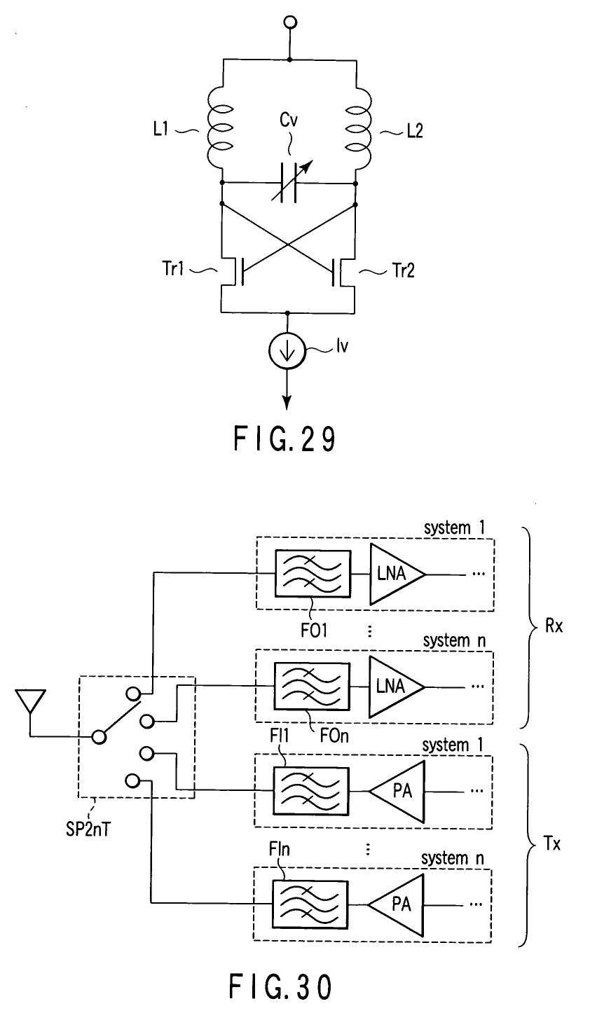

Variable capacitors according to the embodiments of the present invention can be used for circuits other than antenna matching circuits, e.g., VCOs. FIG. 29 is a circuit diagram showing a VCO circuit equipped with a MEMS variable capacitor. This circuit comprises inductors L1 and L2, transistors Tr1 and Tr2, constant current source Iv, and MEMS variable capacitor Cv. The oscillation frequency of the circuit is changed by changing the capacitive value of the MEMS variable capacitor Cv.

FIG. 30 is a circuit diagram showing an example of an arrangement in a case wherein a switch according to the embodiments of the present invention is used as a MEMS switch designed for a multiband cellular phone. In the multiband cellular phone shown in FIG. 30, n output systems Rx and n input systems Tx are switched by a MEMS switch SP2nT. Filters FI1 to FIn are provided at the input stages of the respective output systems Rx, and filters FO1 to FOn are provided at the output stages of the respective input systems Tx.

As described above, according to one aspect of this invention, a semiconductor device which can obtain large contact force with a low driving voltage can be obtained.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
an elastic member having one end which is fixed on a substrate through an anchor so as to form a gap between said one end and the substrate and is deformed to change a distance between the substrate and the other end of the elastic member;
a first electrode which is placed at said other end of the elastic member;
a second electrode which is placed on the substrate so as to face the first electrode;
a piezoelectric actuator which is placed in the elastic member and is deformed to bring said other end of the elastic member close to the substrate; and
an electrostatic actuator which includes a third electrode placed in the elastic member and a fourth electrode placed on the substrate so as to face the third electrode and is deformed to bring said other end of the elastic member close to the substrate,
wherein a distance between the first electrode and the second electrode is changed by driving the piezoelectric actuator and the electrostatic actuator.

2. A device according to claim 1, wherein the piezoelectric actuator is placed between the anchor and the first electrode, and the third electrode is placed between the piezoelectric actuator and the first electrode.

3. A device according to claim 1, wherein one electrode of the piezoelectric actuator is connected to the third electrode of the electrostatic actuator.

4. A device according to claim 1, wherein the piezoelectric actuator includes an upper electrode for piezoelectric driving, a piezoelectric film, and a lower electrode for piezoelectric driving, and either the upper electrode for piezoelectric driving or the lower electrode for piezoelectric driving is electrically connected to the third electrode.

5. A device according to claim 4, wherein the piezoelectric film contains AlN or PZT.

6. A device according to claim 1, further comprising an insulating film interposed between the first electrode and the second electrode.

7. A device according to claim 1, wherein the first electrode and second electrode whose surfaces facing the gap are exposed, are electrically connected to each other when the elastic member and the substrate are brought close to each other, and are electrically separated from each other when the elastic member and the substrate are separated from each other.

8. A device according to claim 1, further comprising a contact which applies a potential to the first electrode.

9. A semiconductor device comprising:
an elastic member having two ends which are fixed on a substrate through a first anchor and second anchor so as to form a gap in a middle portion and is deformed to change a distance between the middle portion and the substrate;
a first electrode which is placed at the middle portion of the elastic member;
a second electrode which is placed on the substrate so as to face the first electrode;
a first piezoelectric actuator and a second piezoelectric actuator which are placed in the elastic member with the first electrode being placed therebetween in a horizontal direction and deform the middle portion of the elastic member so as to bring the middle portion close to the substrate; and
a first electrostatic actuator and a second electrostatic actuator which includes a third electrode and fourth electrode placed in the elastic member with the first electrode being placed therebetween in a horizontal direction, and a fifth electrode and sixth electrode placed on the substrate to face the third electrode and the fourth electrode, and deforms the middle portion of the elastic member to bring the middle portion close to the substrate,
wherein a distance between the first electrode and the second electrode is changed by driving the first piezoelectric actuator and second piezoelectric actuator and the first electrostatic actuator and second electrostatic actuator.

10. A device according to claim 9, wherein the first piezoelectric actuator and second piezoelectric actuator are arranged between the first anchor and the second anchor, the third electrode is placed between the first piezoelectric actuator and the first electrode, and the fourth electrode is placed between the second piezoelectric actuator and the first electrode.

11. A device according to claim 9, wherein one electrode of the first piezoelectric actuator is connected to the third electrode of the electrostatic actuator, and one electrode of the second piezoelectric actuator is connected to the fourth electrode of the electrostatic actuator.

12. A device according to claim 9, wherein the first piezoelectric actuator includes a first upper electrode for piezoelectric driving, a first piezoelectric film, and a first lower electrode for piezoelectric driving, with the first upper electrode or the first lower electrode being electrically connected to the third electrode, and
the second piezoelectric actuator includes a second upper electrode for piezoelectric driving, a second piezoelectric film, and a second lower electrode for piezoelectric driving, with the second upper electrode or the second lower electrode being electrically connected to the fourth electrode.

13. A device according to claim 12, wherein the first piezoelectric film and second piezoelectric film contain AlN or PZT.

14. A device according to claim 9, further comprising an insulating film interposed between the first electrode and the second electrode.

15. A device according to claim 9, wherein the first electrode and second electrode whose surfaces facing the gap are exposed, are electrically connected to each other when the elastic member and the substrate are brought close to each other, and are electrically separated from each other when the elastic member and the substrate are separated from each other.

16. A device according to claim 9, further comprising a contact which applies a potential to the first electrode.

17. A device according to claim 9, which further comprises:
a third piezoelectric actuator which is provided on the first anchor side of the elastic member and deforms the middle portion of the elastic member so as to bring the middle portion close to the substrate; and
a fourth piezoelectric actuator which is provided on the second anchor side of the elastic member and deforms the middle portion of the elastic member so as to bring the middle portion close to the substrate, and
in which the first piezoelectric actuator and third piezoelectric actuator are arranged to face each other through the first electrostatic actuator, and the second piezoelectric actuator and fourth piezoelectric actuator are arranged to face each other through the second electrostatic actuator.

18. A device according to claim 9, wherein the first piezoelectric actuator and second piezoelectric actuator respectively have flexure portions functioning as springs.

19. A matching circuit system comprising:
a driver which converts a channel select information into a capacitive value selection signal; and
a matching circuit which receives the capacitive value selection signal from the driver, and is set as the capacitive value accordance with the channel select information, the matching circuit includes variable capacitors connected in parallel,
wherein each of the variable capacitors including:
an elastic member having two ends which are fixed on a substrate through a first anchor and second anchor so as to form a gap in a middle portion and is deformed to change a distance between the middle portion and the substrate;
a first electrode which is placed at the middle portion of the elastic member;
a second electrode which is placed on the substrate so as to face the first electrode;
a first piezoelectric actuator and a second piezoelectric actuator which are placed in the elastic member with the first electrode being placed therebetween in a horizontal direction and deform the middle portion of the elastic member so as to bring the middle portion close to the substrate; and
a first electrostatic actuator and a second electrostatic actuator which includes a third electrode and fourth electrode placed in the elastic member with the first electrode being placed therebetween in a horizontal direction, and a fifth electrode and sixth electrode placed on the substrate to face the third electrode and the fourth electrode, and deforms the middle portion of the elastic member to bring the middle portion close to the substrate,
wherein a distance between the first electrode and the second electrode is changed by driving the first piezoelectric actuator and second piezoelectric actuator and the first electrostatic actuator and second electrostatic actuator.
